(19) United States
(12) Patent Application Publication
(10) Pub. No.: US 2013/0235539 A1
(43) Pub. Date: Sep. 12, 2013

(54) WATERPROOF STRUCTURE

(71) Applicant: KABUSHIKI KAISHA TOSHIBA, Tokyo (JP)

(72) Inventors: Seiji HASHIMOTO, Ome-shi (JP); Tetsuo OKAZAKI, Hino-shi (JP)

(73) Assignee: KABUSHIKI KAISHA TOSHIBA, Tokyo (JP)

(21) Appl. No.: 13/735,206

(22) Filed: Jan. 7, 2013

(30) Foreign Application Priority Data
Mar. 9, 2012 (JP) 2012-052913

(51) Int. Cl. H05K 5/06

(52) U.S. Cl. CPC H05K 5/06
USPC 361/752

(57) ABSTRACT

According to one embodiment, a waterproof structure includes a casing, a circuit board, a lens part and a transparent member. The casing includes a wall including a first opening. The circuit board is stored in the casing, the circuit board with an electronic component mounted thereupon, the electronic component facing the first opening. The lens part is exposed outside the casing, at least a part of the lens part being in the first opening. The transparent member is fixed to the wall from an inside of the casing, the transparent member configured to seal the first opening.

### CROSS-REFERENCE TO RELATED APPLICATIONS

This application is based upon and claims the benefit of priority from prior Japanese Patent Application No. 2012-052913, filed Mar. 9, 2012, the entire contents of which are incorporated herein by reference.

### FIELD

Embodiments described herein relate generally to a waterproof structure.

### BACKGROUND

An electronic apparatus such as a TV, personal computer, tablet computer, personal digital assistant (PDA), and cellular phone may comprise a waterproof structure.

To obtain the desired waterproof characteristics, the design of such an electronic apparatus comprising a waterproof structure may be limited.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view showing a TV according to a first embodiment;

FIG. 2 is an exemplary cross-sectional view showing the TV of the first embodiment, taken along line F2-F2 of FIG. 1;

FIG. 3 is an exemplary front view showing a part of the TV of the first embodiment;

FIG. 4 is an exemplary front view showing an example of transformation of the TV of the first embodiment;

FIG. 5 is an exemplary front view showing lens parts of the first embodiment;

FIG. 6 is an exemplary front view showing the lens parts of the first embodiment from an opposite side to FIG. 5;

FIG. 7 is an exemplary front view showing a part of a mask and a transparent member of the first embodiment in a disassembled fashion;

FIG. 8 is an exemplary perspective view of the transparent member and a third double-sided tape of the first embodiment;

FIG. 9 is an exemplary cross-sectional view showing an example of a manufacturing process of the TV of the first embodiment;

FIG. 10 is an exemplary front view showing a base and module circuit board of the first embodiment in a disassembled fashion;

FIG. 11 is an exemplary perspective view showing a tablet computer according to a second embodiment;

FIG. 12 is an exemplary perspective view showing a part of the slate computer of the second embodiment;

FIG. 13 is an exemplary perspective view showing the tablet computer of the second embodiment in a disassembled fashion;

FIG. 14 is an exemplary perspective view showing a part of the disassembled tablet computer of the second embodiment; and

FIG. 15 is an exemplary cross-sectional view of a part of a tablet computer according to a third embodiment.

### DETAILED DESCRIPTION

Various embodiments will be described hereinafter with reference to the accompanying drawings.

In general, according to one embodiment, a waterproof structure includes a casing, a circuit board, a lens part and a transparent member. The casing includes a wall including a first opening. The circuit board is stored in the casing, the circuit board with an electronic component mounted thereupon, the electronic component facing the first opening. The lens part is exposed outside the casing, at least a part of the lens part being in the first opening. The transparent member is fixed to the wall from an inside of the casing, the transparent member configured to seal the first opening.

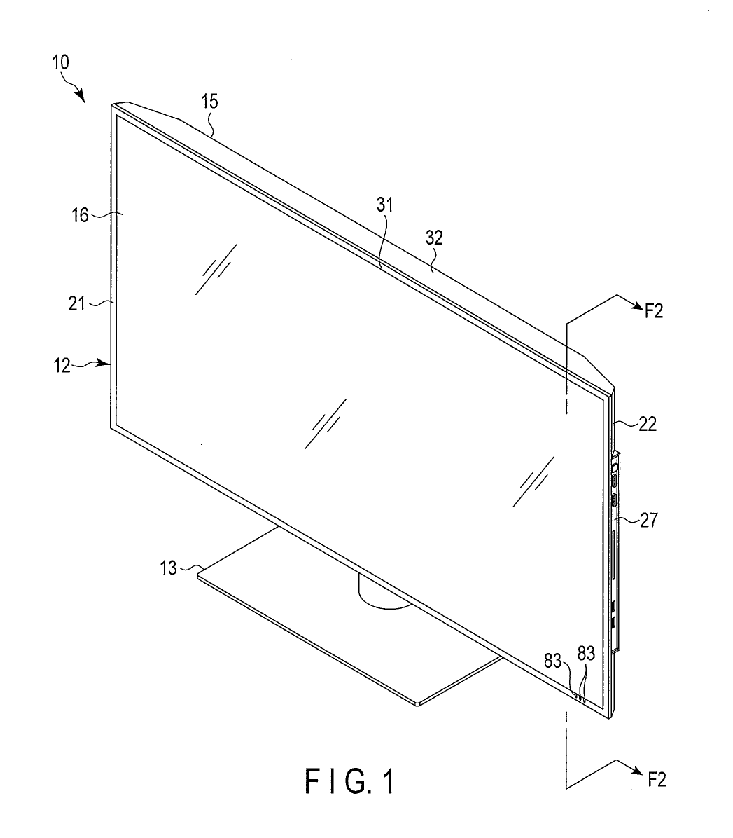

Hereinafter, a first embodiment is described referring to FIGS. 1 to 10. In the present specification, it is defined that a before side (that is, a user side) is referred to as a front direction, a far side of the user side is referred to as a rear direction, a left side of the user side is referred to as a left direction, a right side of the user side is referred to as a right direction, an upward side of the user side is referred to as an upper direction, and a lower side of the user side is referred to as a lower direction. If a single element can be referred to by a plurality of names, such names are added thereto. However, it does not mean that a single element which is referred to by a single name is limited to the single name, or the additional names are limited thereto.

FIG. 1 is an exemplary perspective view showing a television receiver (hereinafter referred to as TV) 10. The TV 10 is an electronic apparatus and an example of a waterproof structure. As shown in FIG. 1, the TV 10 comprises a TV main body (TV, television receiver, main body, display apparatus) 12 and a stand 13. The stand 13 is rotatably connected to the TV main body 12. The stand 13 is placed on a ground surface (outer surface, flat surface, surface) such as a TV rack to support the TV main body 12.

The TV main body 12 comprises a casing (cabinet, exterior portion, wall) 15 and a display module (a display apparatus, display part, electronic part, part) 16. The display module 16 is, for example, a liquid crystal display. The display module is not limited to the liquid crystal display, and may be a plasma display or an organic electroluminescence display. The display module 16 is stored in the casing 15.

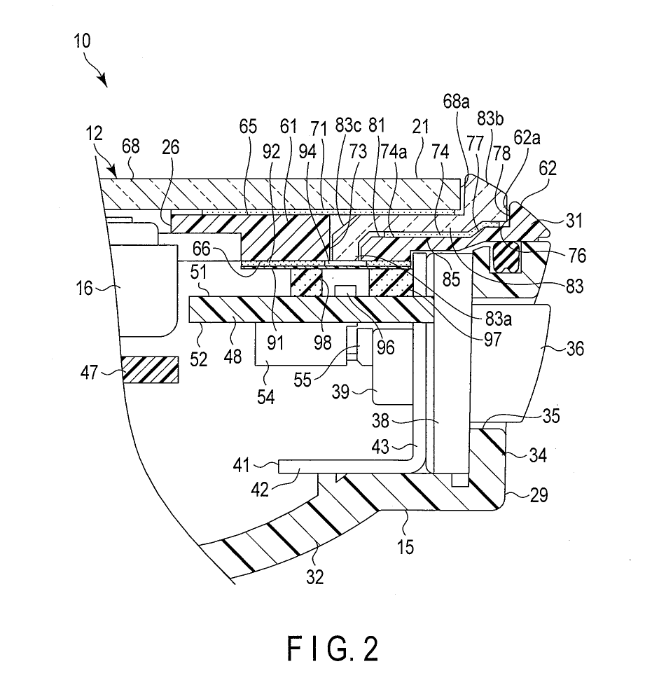

FIG. 2 is an exemplary cross-sectional view showing a part of the TV taken along line F2-F2 of FIG. 1. The casing 15 comprises a front surface 21 and side surface (outer surface, surface, sidewall, wall portion, wall) 22. The side surface 22 is positioned at a right side from a user's standpoint. As shown in FIG. 2, the front surface 21 comprises a rectangular display opening 26. In other words, the front surface 21 is formed in a shape of a frame surrounding the display opening 26. The display opening 26 exposes a display surface of the display module 16 configured to display an image.

The side surface 22 is a surface to substantially cross the front surface 21. A part of the side surface 22 is inclined from the front surface 21 toward a rear direction in a manner to come close to a center part of the TV main body 12. The side surface 22 comprises an interface portion 27. The interface portion 27 is formed to project from the side surface 22.

The interface portion 27 comprises a plurality of buttons (switches, manipulated portions, parts, members, input portions) and a plurality of openings. The buttons are, for example, channel switching buttons and volume control buttons. Into the openings, for example, a card such as a B-CAS card and connectors such as a USB connector and HDMI connector are inserted.

The casing 15 further comprises a rear surface positioned on an opposite side to the front surface 21, and a lower surface 29 shown in FIG. 2. The lower surface 29 crosses the front surface 21. The rear surface comprises, for example, a plurality air holes and the stand 13 fixed thereto. The lower surface 29 comprises a plurality of speaker openings configured to, for example, output sound.

As shown in FIG. 2, the casing 15 comprises a mask (cover, covering portion, exterior portion, member, part) 31 and a base (cover, base portion, exterior portion, member, part) 32. The mask 31 is an example of a first member.

The mask 31 and base 32 are formed of, for example, synthetic resin. The mask 31 forms at least a part of the front surface 21 of the casing 15. The base 32 forms the side surface 22, the lower surface 29 and the rear surface.

The base 32 comprises a sidewall (wall, side portion) 34 which forms the lower surface 29 of the casing 15. The sidewall 34 comprises a button opening (hole, concave part, inserted part) 35. A button member (manipulated portion, input portion) 36 is inserted into the button opening 35. The button member is, for example, a power button. A first end portion of the button member 36 is exposed outside the casing 15. A second end portion of the button member 36 engages with the sidewall 34 inside the casing 15 to prevent the button member 36 from slipping out of the casing 15 from the button opening 35.

A keypad 38 covers the button opening 35 and the second end portion of the button member 36 from the inside of the casing 15. The keypad 38 is formed of synthetic rubber such as, for example, silicon rubber. The keypad 38 contacts the sidewall 34 in a watertight fashion and seals the button opening 35.

The keypad 38 comprises a projection 39 projecting toward the inside of the casing 15. When the button member 36 is pushed by a user from the outside of the casing 15, the keypad 38 elastically deformed. Thereby, the projection 39 is elastically displaced toward the inside of the casing 15.

A fixing member 41 is attached to the inside of the casing 15. The fixing member 41 is formed of, for example, a metal plate bent in an L-shape. The fixing member 41 comprises an attachment portion 42 and retaining portion 43.

The attachment portion 42 is formed in a rectangular shape, and fixed to the casing 15 by, for example, welding. The retaining portion 43 is formed in a rectangular shape and is substantially orthogonal to the attachment portion 42. The retaining portion 43 faces the sidewall 34 from the inside of the casing 15 and pushes a part of the keypad 38 to the sidewall 34. Thereby, the keypad 38 is interposed between the sidewall 34 and retaining portion 43 to contact the sidewall 34 in a watertight fashion.

The casing stores a main circuit board (mother board, part) 47 and a module circuit board (daughter board, wire board, circuit board, part) 48. The module circuit board 48 is an example of a circuit board.

The main circuit board 47 is, for example, a printed circuit board. Various electronic parts such as an LSI are mounted on the main circuit board 47. The main circuit board 47 is attached to a display module 16 through, for example, a spacer, and connected to the module circuit board 48 by, for example, a cable.

At least a part of the module circuit board 48 faces the mask 31 from the inside of the casing 15. The module circuit board 48 is placed to be substantially orthogonal to the sidewall 34. The module circuit board 48 is closer to the sidewall 34 than the main circuit board.

The module circuit board 48 comprises a first surface (region, portion) 51 and a second surface (region, portion) 52. The first surface 51 faces the mask 31. The second surface 52 is positioned at an opposite side to the first surface 51. Various electronic parts such as switch 54 and condenser, etc. are mounted on the second surface 52.

The switch 54 comprises a manipulated portion 55 projecting toward a button opening 35. When the manipulated portion 55 is pushed, the switch 54 is manipulated. A tip of the manipulated portion 55 contacts a tip of the projection 39 of the keypad 38. When a user pushes the button member 36, the elastically displaceable projection 39 of the keypad 38 pushes the manipulated portion 55. Thereby, the switch 54 is manipulated.

As shown in FIG. 2, the mask 31 comprises a wall portion (portion, wall, region) 61 and a edge portion (outer periphery, frame portion, protrusion, projection) 62. The wall portion 61 is formed in a frame shape to surround the display opening 26. The edge portion 62 is formed in a frame shape to surround the wall portion 61.

The wall portion 61 comprises a substantially flat outer surface (one surface, first surface, region) 65 and a substantially flat inner surface (other surface, second surface, region) 66. The outer surface 65 faces the outside of the casing 15. The inner surface 66 is placed at an opposite side to the outer surface 65 and faces the inside of the casing 15. The inner surface 66 faces at least a part of the module circuit board 48.

A transparent panel (board, protection portion, covering portion, transparent portion) 68 is attached to the outer surface 65 of the wall portion 61. The panel 68 is an example of a second part, and for example, a glass panel. The panel 68 covers the display opening 26 and forms a part of the front surface 21 of the casing 15. The display portion of the display module 16 is exposed outside the casing 15 over the panel 68.

A first double-sided tape (adhering part, adhering layer, stacking portion, fixing portion, attachment portion, waterproofing portion, water-resistant portion) 71 is interposed between the outer surface 65 of the wall portion 61 and the panel 68. The first double-sided tape 71 is an example of the first adhering part. The first double-sided tape 71 is formed in a frame shape corresponding to the shape of the outer surface 65 of the wall portion 61.

The panel 68 is fixed to the outer surface 65 by the first double-sided tape 71. Here, the fixing material is not limited to the first double-sided tape 71, but for example, an adhesive agent or other synthetic resin may be used to fix the panel 68 to the outer surface 65. The first double-sided tape 71 is waterproof to prevent liquid from entering the inside of the casing 15 through a gap between the outer surface 65 of the wall portion 61 and the panel 68.

The wall portion 61 comprises a plurality of first openings (apertures, holes, concave portions) 73 and a plurality of grooves (recesses, concave portions) 74. Here, FIG. 2 shows a single first opening 73 and a single groove 74. Hereinafter, the explanation is given referring to the single first opening 73 and the single groove 74 unless otherwise specified.

The first opening 73 opens over the outer surface 65 and inner surface 66. At least a part of the first opening 73 is covered by the panel 68. The groove 74 is provided on the outer surface 65. The panel 68 covers at least a part of the groove 74.

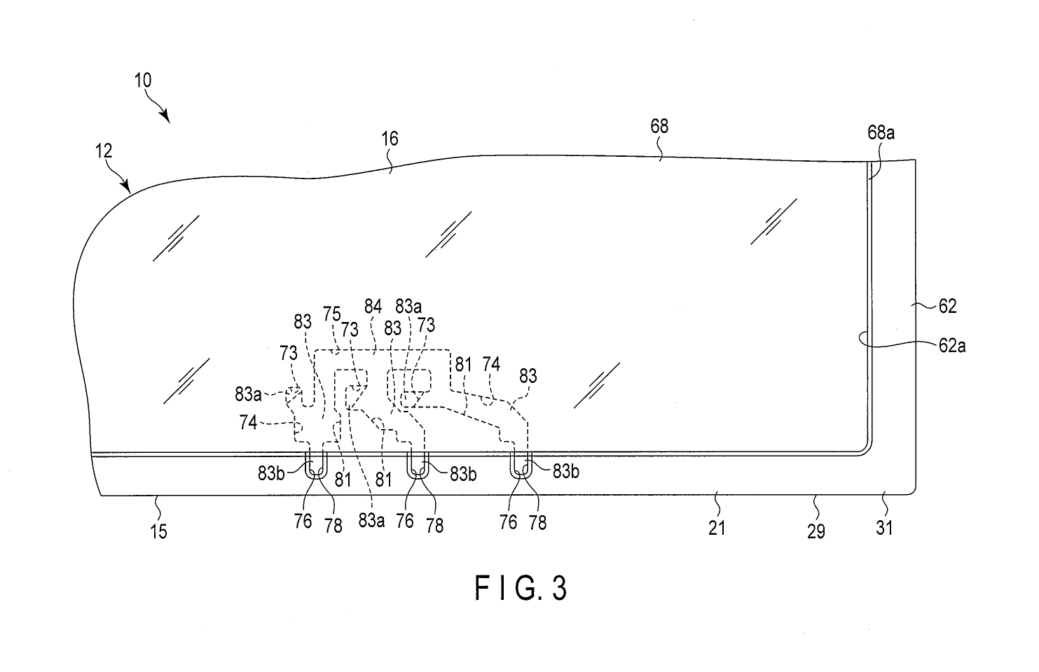

FIG. 3 is an exemplary front view showing a part of the TV 10. As shown in FIG. 3 with a broken line, a first end of the groove 74 continues to the first opening 73. The groove 74 extends from the first opening 73 to the edge portion 62. In other words, the groove 74 extends to be distant from the display opening 26. As shown in FIG. 3, the groove 74 may comprise a plurality bent portions.

A second end of the groove 74 forms a notched portion (hole, groove, recess, concave portion) 76 on the edge portion 62. The notched portion 76 is formed in substantially a U-shape. As shown in FIG. 2, a step portion (convex portion, projection, protrusion) 77 protruding outside the casing 15 is formed at a bottom surface 74a of the groove 74. As shown in FIG. 3, the grooves 74 are connected to each other by connecting grooves 75.

As shown in FIG. 2, the edge portion 62 projects from the outer surface 65 of the wall portion 61. An inner edge (edge, inner periphery, end) 62a of the edge portion 62 faces an outer edge (periphery, outer periphery, end) 68a of the panel 68.

The outer edge 68a of the panel 68 and the notched portion 76 formed on the edge portion 62 form a second opening 78. In other words, the mask 31 and the panel 68 form the second opening 78. The formation of the second opening 78 is not limited thereto and may be formed at other positions such as panel 68.

The second opening 78 opens on the outside of the casing 15. The second opening 78 has a shape different from the first opening 73. Here, the first opening 73 and the second opening 78 may have the same shape.

As shown in FIG. 3, the second opening 78 is formed at a position shifted from the first opening 73. In other words, when looking the front surface 21 in front, it is recognized that at least a part of the second opening 78 is out of the first opening 73.

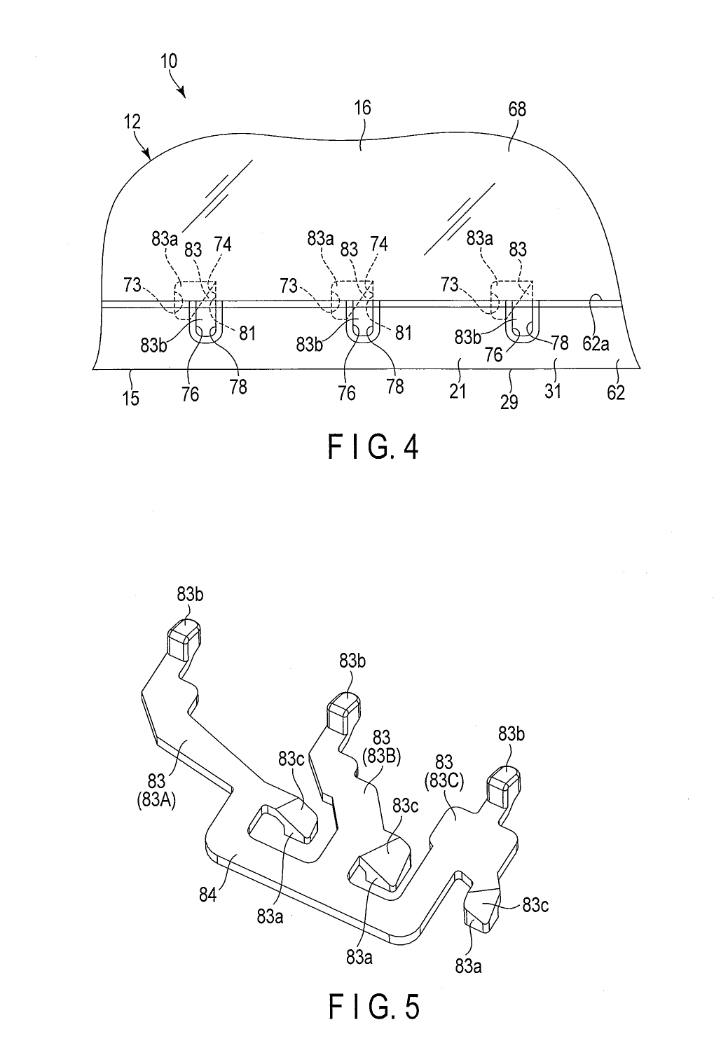

FIG. 4 is an exemplary front view showing an example of a transformation of the TV 10. As shown in FIG. 4, the first opening 73 and a part of the second opening 78 may overlap with each other. As shown in FIGS. 3 and 4, at least a part of the second opening 78 is placed at a position shifted from the first opening 73.

As shown in FIG. 2, an intermediate part (hole, gap, path, region) 81 is formed by the groove 74 on the outer surface 65 of the wall portion 61 and the panel 68. In other words, the intermediate part 81 is formed by the mask 31 comprising the groove 74 and the panel 68 covering the groove 74. The intermediate part 81 connects the first opening 73 and the second opening 78. In other words, the second opening 78 connects with the first opening 73 through the intermediate part 81. Or, further in other words, the intermediate part 81 is provided between the first opening 73 and the outside of the casing 15.

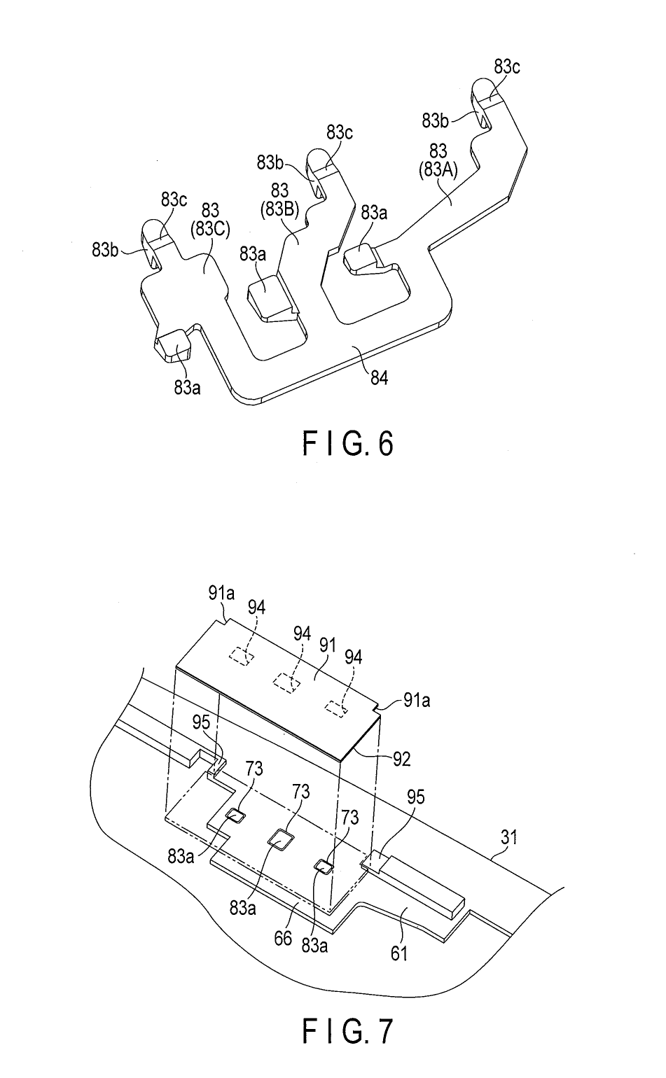

FIG. 5 is an exemplary perspective view showing lens parts 83. FIG. 6 is an exemplary perspective view showing the lens parts 83 viewed from the opposite side to FIG. 5. As shown in FIG. 2, a plurality of lens parts (transparent portions, light guiding portions, reflective portions, members) 83 are attached to the mask 31.

A part of the lens part 83 is stored in the intermediate part 81. As shown in FIGS. 5 and 6, a part of the lens parts (connecting portions, intermediate portions, light guiding portions) 83 is formed in a plate shape to correspond to the shape of the intermediate part 81.

For example, a lens part 83 at a left side in FIG. 5 (referred to as “lens part 83A” for the sake of clarification) comprises a rectangular first portion, a rectangular second portion, and a third portion. The first portion extends from the first end 83a along the edge portion 62. The second portion crosses the first portion and extends toward the second end 83b. The third portion projects from a portion where the first portion and the second portion cross. At the portion where the first portion and the second portion of the lens part 83A cross, an opposite side of the third part is planed off.

A lens part 83 at a center in FIG. 5 (referred to as “lens part 83B” for the sake of clarification) comprises a rectangular first portion, a second portion, and a rectangular third portion. The first portion extends from the first end 83a along the edge portion 62. The second portion extends slantwise with respect to the first portion. The third portion extends from the end of the second portion in a direction orthogonal to the first portion. The second portion is bent at about the intermediate portion. The second portion comprises a portion projecting in a direction where the second end 83b exists.

A lens part 83 at a right side in FIG. 5 (referred to as “lens part 83C” for the sake of clarification) comprises a rectangular first portion, a rectangular second portion, and a rectangular third portion. The first portion extends from the first end 83a to an outer periphery of the edge portion 62. The second portion is connected to the first portion and larger than the first portion. The third portion extends from the second portion to a second end 83b. A portion where the first portion and the second portion connect to each other inclines in a direction to where the first portion extends.

As explained above, each of lens parts 83A, 83B and 83C comprises a rectangular portion, inclined an extending portion, and a projecting portion. In other words, each of lens parts 83A, 83B and 83C has a winding (wavy, meandering) shape. Thereby, light from the first end 83a of the lens part 83 reflects at each portion and go toward the second end 83b of the lens part 83.

The projecting portion of each of the lens parts 83A, 83B and 83C engages with the intermediate part 81. Thereby, each of lens parts 83A, 83B and 83C stably fits in the intermediate part 81, and unsteady movement of the lens parts 83 is prohibited (cf. FIG. 14).

A first end (light inlet portion, light outlet portion) 83a of the lens 83 projects from a first surface of a plate-like portion of the lens part 83. A second end (light inlet portion, light outlet portion) 83b of the lens 83 projects from a second surface of the plate-like portion of the lens part 83. In other words, the first end 83a of the lens part 83 projects to an opposite side to the second end 83b of the lens part 83.

Inclined portions (refraction portion, reflection portion) 83c are formed near the first end 83a and the second end 83b of the lens part 83. The inclined portions 83c reflect light from the first end 83a of the lens part 83 toward the second end 83b.

The lens parts 83 are connected to each other by connecting portion 84. The connecting portion 84 is connected to part of the plate-shaped portions of the lens parts 83. The lens parts 83 and connecting portion 84 are formed integrally.

The connecting portion 84 is located inside of the mask 31 deeper than the lens parts 83. The connecting portion 84 comprises a first rectangular portion extending along the edge portion 62 and three second portions each extending from the first portion to a direction orthogonal to the first portion. The second portions are connected to the lens parts 83, respectively, from the opposite side of the second end 83b of the lens parts 83.

The lens parts 83 are formed of transparent resin, for example. Light comes in and goes out from the first end 83a and the second end 83b of the lens part 83, and the light reflects inside the lens part 83. Thus, light which enters the first end 83a of the lens part 83 exits outside from the second end 83b of the lens part 83.

The lens parts 83 are adhered to the bottom surface 74a of the groove 74 by a second double-sided tape (adhering part, adhering layer, stacking portion, fixing portion, attachment portion, waterproofing portion, water-resistant portion) 85. In other words, the second double-sided tape 85 is interposed between the lens parts 83 and the groove 74. The second double-sided tape is an example of the first adhering part. Here, the fixing material is not limited to the second double-sided tape 71, but for example, an adhesive agent or other synthetic resin may be used to fix the lens parts 83 to the groove 74. The second double-sided tape 85 is waterproof to prevent liquid from entering the inside of the casing 15 through a gap between the lens parts 83 and the groove 74.

A part of the first double-sided tape 71 is adhered to a part of the lens parts 83. The lens parts 83 are fixed to the panel 68 by the first double-sided tap 71. That is, the first double-sided tape fixes the panel 68 to the mask 31 and the lens part 83 to the panel 68.

A part of the intermediate part 81 on which the lens parts 83 are placed is blocked by the first double-sided tape 71 and second double-sided tape 85. That is, the gap between the lens parts 83 and the panel 68 is sealed by the first double-sided tape 71 and a part of the gap between the lens parts 83 and the bottom surface 74a of the groove 74 is sealed by the second double-sided tape 85. That is, the gap between the intermediate part 81 and the lens parts 83 is narrowed by the first and second double-sided tapes 71 and 85.

The first end 83a of the lens part 83 is stored in the first opening 73. The first end 83a of the lens part 83 is exposed inside the casing 15 from the first opening 73. The first end 83a of the lens parts 83 forms a flat surface substantially the same with the inner surface 66 of the wall portion 61.

A part of the second end 83b of the lens part 83 is stored in the second opening 78. The second end 83b of the lens part 83 is exposed outside the casing 15 from the second opening 78. The second end 83b of the lens part 83 projects from the outer surface of the edge portion 62. Thereby, the second end 83b is easily recognizable by a user. Here, the second end 83b of the lens parts 83 may be formed as a recess in the outer surface of the edge portion 62.

FIG. 7 is an exemplary perspective view of disassembled state of a part of the mask 31 and a transparent member 91. As shown in FIG. 7, the transparent member (transparent part, covering part, closing part, waterproof part, water-resistant part) 91 is attached to the inner surface 66 of the wall portion 61. The transparent member 91 is, for example, a transparent film formed of polyethylene-terephthalate. The transparent member 91 is water resistant and shuts out liquid.

As shown in FIG. 2, the transparent member 91 covers the first opening 73 and faces the inner surface 66 of the wall portion 61. The transparent member 91 is fixed to the inner surface 66 by a single third double-sided tape (adhering part, adhering layer, stacking portion, fixing portion, attachment portion, waterproofing portion, water-resistant portion) 92. In other words, the third double-sided tape 92 is interposed between the inner surface 66 and the transparent member 91. The third double-sided tape 92 is an example of the second adhering part. Here, the fixing material is not limited to the third double-sided tape 92, but for example, an adhesive agent or other synthetic resin may be used to fix the transparent member 91 to the inner surface 66.

The third double-sided tape 92 is waterproof to prevent liquid from entering the inside of the casing 15 through a gap between the inner surface 66 of the wall portion 61 and the transparent member 91. The transparent member 91 blocks the first opening 73 from the inside of the casing 15.

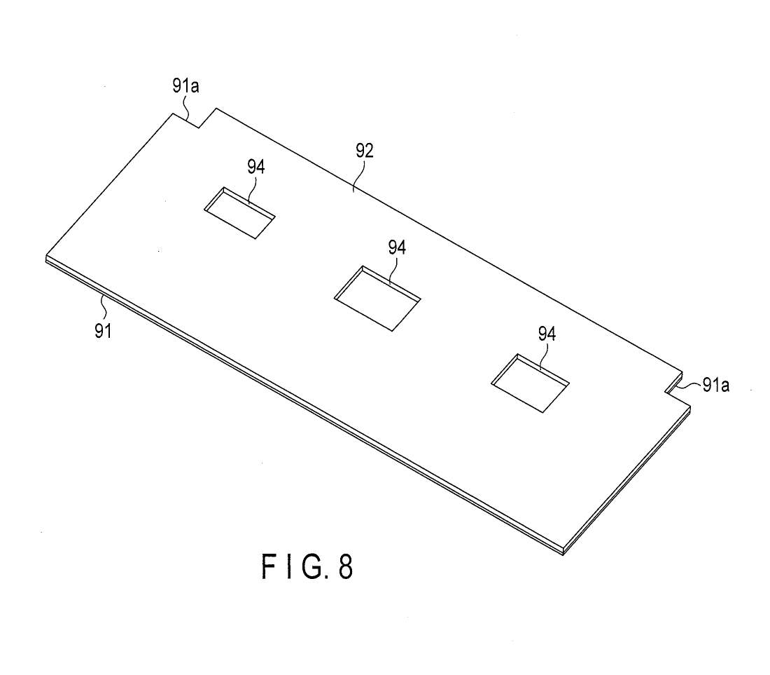

FIG. 8 is an exemplary perspective view showing the transparent member 91 and the third double-sided tape 92. As shown in FIG. 8, a plurality of holes (openings, transparent parts) 94 are provided on the third double-sided tape 92. The holes 94 are placed at a position corresponding to the first opening 73 and larger than the first opening 73.

The transparent member 91 is formed in a substantially rectangular shape. Some of corners 91a of the transparent member 91 are concave. As shown in FIG. 7, a pair of convex portions 95 is provided on the inner surface 66 of the wall portion 61. The concave corners 91a of the transparent member 91 engage with the convex portions 95, respectively. The convex portions 95 are used to position the transparent member 91.

As shown in FIG. 2, a plurality of LEDs (parts, implemented parts, light emitting devices) 96 are mounted on a first surface 51 of the module circuit board 48. The LEDs 96 are an example of electronic components. The LEDs 96 are arranged corresponding to the first openings 73. The LEDs 96 face the first openings 73. Furthermore, the LEDs 96 face the first ends 83a of the lens parts 83 stored in the first openings 73.

The LEDs 96 emit light with electrification. The electronic components are not limited to the LEDs 96, and for example, the other electronic components configured to emit light such as organic electroluminescent or optical sensors such as illumination sensor and CMOS sensor.

A pressing member (light blocking portion, interposing portion, containing portion) 97 is attached to the first surface 51 of the module circuit board 48. The pressing member 97 is, for example, a black sponge. A plurality of containing portions (holes, openings, insertion portions) 98 are provided in the pressing member 97. The containing portions 98 open toward the first openings 73 and the containing portions 98 are holes larger than the first openings 73. The containing portions 98 store the LEDs 96, respectively. That is, the pressing member 97 surrounds the LEDs 96.

As shown in FIG. 2, in a width direction of the pressing member 97, the containing portions 98 are closer to the center of the module circuit board 48 as compared to a center of the width direction of the pressing member 97. In other words, around the containing portions 98, a part of the pressing member 97 closer to the center of the module circuit board 48 is formed thinner than a part of the pressing member distant from the center of the module circuit board 48.

The pressing member 97 is interposed between the module circuit board 48 and the wall portion 61. The pressing member 97 contacts the transparent member 91 and presses the transparent member 91 against the wall portion 61. Furthermore, the pressing member 97 prevents the light from the LEDs 96 from leaking into the inside of the casing 15.

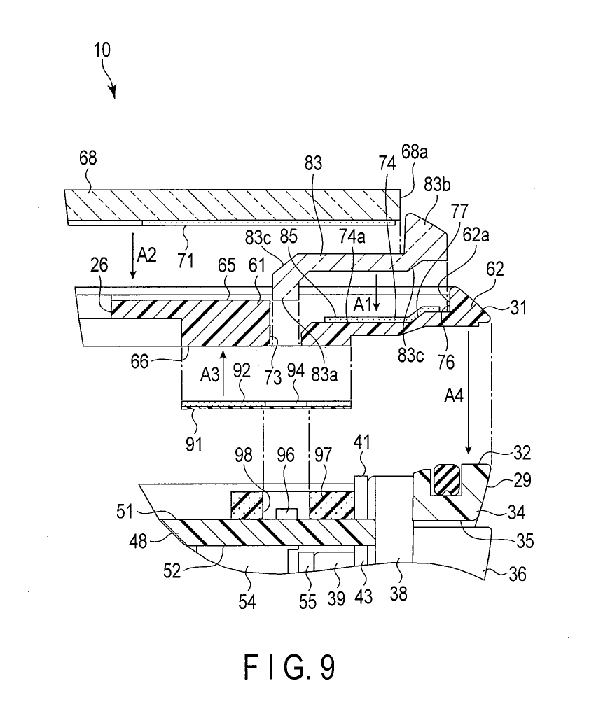

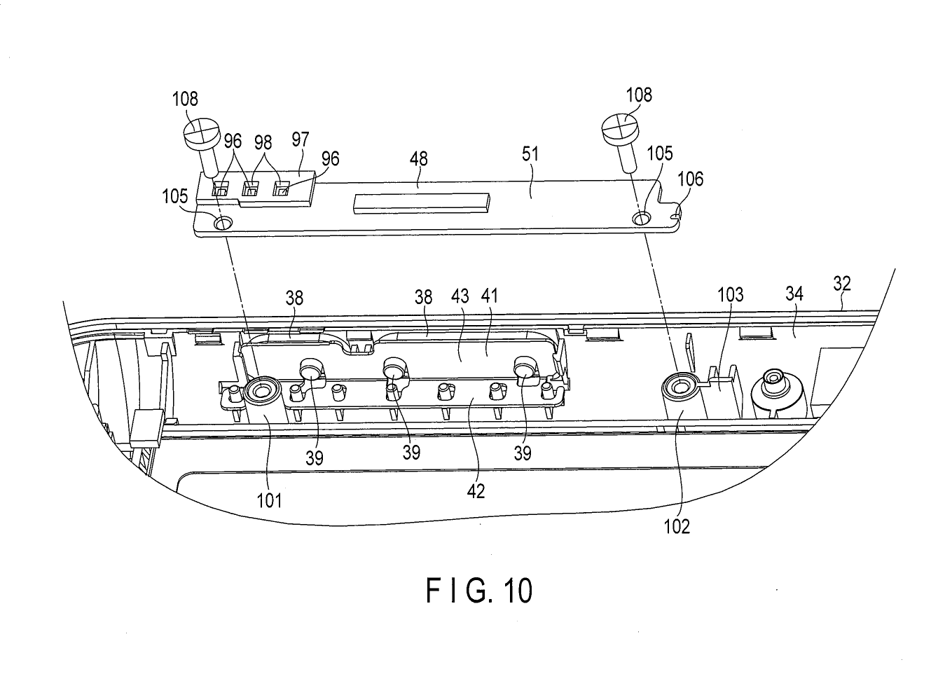

Hereinafter, referring to FIGS. 9 and 10, a part of manufacturing a TV 10 is described. The manufacturing method of the TV 10 is not limited to the following process. FIG. 9 is an exemplary cross-sectional view of the TV 10 and it shows an example of the manufacturing method of the TV 10. FIG. 10 is an exemplary perspective view showing base 32 and module circuit board 48 in a disassembled fashion.

Firstly, the second double-sided tape 85 is attached to the bottom surface 74a of the groove 74 of the mask 31. Next, as indicated by arrow A1 in FIG. 9, the lens parts 83 are fit in the groove 74 and fixed therein by the second double-sided tape 85.

Then, as shown by arrow A2 in FIG. 9, a panel 68 to which the first double-sided tape 71 is attached is fit in the inside of edge portion 62 of the mask 31. The panel 68 is fixed to the outer surface 65 of the wall portion 61 by the first double-sided tape 71. At the same time, the lens parts 83 are fixed to the panel 68 by the first double-sided tape 71.

Then, as shown by arrow A3 in FIG. 9, the transparent member 91 to which the third double-sided tape 92 is attached is fixed to the inner surface 66 of the wall portion 61. As shown in FIG. 7, when the transparent member 91 is fixed to the wall portion 61, the corners 91a of the transparent member 91 are engaged with the convex portions 95. Thereby, the first opening 73 is sealed by the transparent member 91.

Then, as shown in FIG. 10, the module circuit board 48 is attached to the base 32. The base 32 comprises a pair of bosses (attached parts, fixed portions, supporting portions) 101 and 102, and rib (engagement portion, convex portion) 103. The bosses 101 and 102 and rib 103 project from the bottom of the base 32 toward the mask 31. The rib 103 is provided with the boss 102 integrally.

The module circuit board 48 comprises a pair of screw holes (holes, attachment portions, fixing portions) 105 and a slit (groove, concave portions, engagement portions) 106. The screw holes 105 correspond to the bosses 101 and 102. The slit 106 corresponds to the rib 103.

The module circuit board 48 is placed on the bosses 101 and 102. At that time, the rib 103 fits in the slit 106 of the module circuit board 106. Furthermore, an operation portion 55 of the switch 54 mounted on the module circuit board 48 faces a projection 39 of the keypad 38.

A plurality of fasteners 108 such as, for example, screws are screwed in the bosses 101 and 102 through the screw holes 105. Thereby, the module circuit board 48 is fixed to the bosses 101 and 102 of the base 32. Here, the module circuit board 48 may be fixed to the base 32 by other methods, such as using a hook as a fastener.

Then, as shown by arrow A4 in FIG. 9, the mask 31 is attached to the base 32. The mask 31 is fixed to the base 32 with a hook or a screw. Thereby, the pressing member 97 elastically contacts the transparent member 91 and presses the transparent member 91 to the wall portion 61. The TV 10 is manufactured by such a process as mentioned above.

In the TV 10 structured as above, light from the LEDs 96 passes through the transparent member 91 and enters the first end 83a of the lens part 83. The light reflects inside the lens part 83 placed on the intermediate part 81 between the first opening 73 and the second opening 78, and the light exits from the second end 83b of the lens part 83. That is, when the LEDs emit light, the second end 83b of the lens part 83 emits the light. By lighting up the second ends 83b of the lens parts 83, the TV 10 informs a user of various states such as power on/off state, preset recording/viewing on/off state, communication state and processing state.

If liquid such as water is splashed on a periphery of the second openings 78, the liquid may enters the second openings 78. Since a part of the intermediate part 81 is sealed by the first and second double-sided tapes 71 and 85, at least a part of the liquid entering therein is blocked in the intermediate part 81. Even if the liquid passes through the intermediate part 81, the liquid is blocked by the transparent member 91 and the third double-sided tape 92. The liquid blocked by the transparent member 91 and the third double-sided tape 92 is evaporated by a heat generated by, for example, the LEDs 96 and the other electronic components and ejected out of the casing 15 from the second openings 78.

As described above, the first openings 73 are sealed by the transparent member 91 fixed to the wall portion 61 from the inside of the casing 15. Thereby, liquid such as water is prevented from entering inside the casing 15 from the first openings 73. That is, even the TV 10 whose design exposes the lens parts 83 out of the casing 15 can resist intrusion of liquid. Since it is unnecessary to cover watertightly the lens parts 83 from the outside of the casing 15, design of the waterproof structured TV 10 can be carried out with a great degree of freedom.

The lens parts 83 comprising the first ends 83a stored in the first openings 73 are fixed to the casing 15 by the waterproofing first and second double-sided tapes 71 and 85. Thereby, a part fixing the lens parts 83 is waterproofed, and the waterproof characteristic of the TV 10 is improved. Furthermore, by fixing the lens parts 83 with the first and second double-sided tapes 71 and 85, vibration of the lens parts 83 can be reduced.

The first and second double-sided tapes 71 and 85 block at least a part of a gap between the intermediate part 81 and the lens parts 83. Thereby, liquid such as water is prevented from entering inside the casing 15 through the gap between the intermediate part 81 and the lens parts 83.

The transparent member 91 is fixed to the waterproof third double-sided tape 92 to the wall portion 61. Thereby, a part fixing the transparent member 91 to the wall portion 61 is waterproofed, and the waterproof characteristic of the TV 10 is improved.

At least a part of the second opening 78 is placed at a position shifted from the first opening 73. Thereby, a liquid such as water tends to stay between the second opening 78 and the first opening 73 and the liquid such as water is prevented from entering inside the casing 15.

The second opening 78 is defined by the notched portion 76 on the edge portion 62 and the panel 68. Thereby, the lens parts 83 are easily attached and the TV 10 is easily manufactured.

The casing 15 comprises the intermediate part 81 connecting between the first openings 73 and the second openings 78. The first and second double-sided tapes 71 and 85 cover at least a part of the intermediate part 81. Thereby, liquid such as water is prevented from entering inside the casing 15 through the gap between the intermediate part 81 and the lens parts 83.

The intermediate part 81 is formed by the mask 31 comprising the groove 74 and the panel 68 covering the groove 74. The first double-sided tape 71 fixes the panel 68 to the mask 31 and the lens parts 83 to the panel 68. Thereby, material costs of the TV 10 are reduced and manufacturing steps are also reduced.

The pressing member 97 comprising containing portions 98 to store the LEDs 96 presses the transparent member 91 to the wall portion 61. Thereby, the pressing member 97 prevents the transparent member 91 from peeling off from the wall portion 61 and a liquid such as water from entering inside the casing 15 though a gap between the transparent member 91 and the wall portion 61. Furthermore, the pressing member 97 prevents light leakage from the LEDs 96, and thus, material costs of the TV 10 are reduced.

The grove 74 comprises the steps 77. The steps 77 hold liquid such as water therein. Thereby, a liquid such as water is prevented from entering inside the casing 15.

Around the containing portion 98, a part of the pressing member 97 closer to the center of the module circuit board 48 is formed thinner than a part of the pressing member distant from the center of the module circuit board 48. Thereby, a region of the module circuit board 48 where electronic components are mountable is formed wider.

When the LEDs 96 emit light, the second ends 83b of the lens parts 83 emit the light. Thus, while a liquid such as water is prevented from entering inside the casing 15, the second ends 83b of the lens parts 83 exposed outside the casing 15 can be lite.

Here, instead of the LEDs 96, the TV 10 may comprise an optical sensor such as, for example, an illumination sensor and CMOS sensor. The TV 10 comprising such the optical sensor can detects brightness of the outside of the casing 15 and photograph an image of the outside of the casing 15 while preventing liquid, such as water, from entering inside the casing 15.

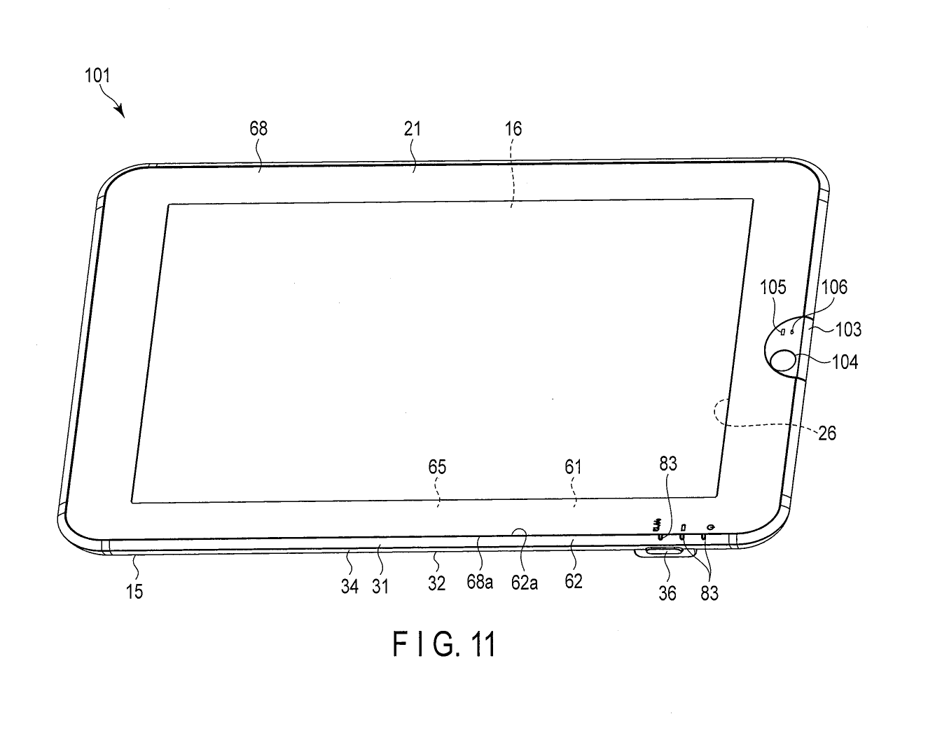

Hereinafter, referring to FIGS. 11 and 14, the second embodiment is described. Here, in the embodiment disclosed below, the same reference numerals are applied to structural elements having the same function as that of the TV 10 in the first embodiment. Furthermore, a part of or the entire explanation of such structural elements may be omitted.

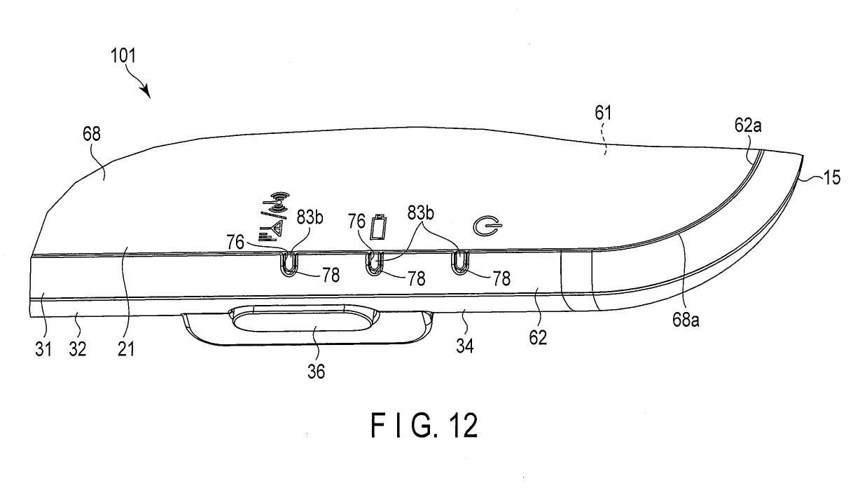

FIG. 11 is an exemplary perspective view of a tablet computer (personal computer, tablet PC, electronic apparatus) 131 according to the second embodiment. FIG. 12 is an exemplary perspective view showing a part of the tablet computer 131 enlarged. The tablet computer 131 is an example of a waterproof structure.

As shown in FIG. 11, the tablet computer 131 comprises a casing 15. The casing 15 comprises a mask 31 forming a front surface 21 of the casing 15 and a base 32. The base 32 comprises a sidewall 34 forming a side surface of the casing 15.

The front surface 15 of the casing 15 comprises a camera part (portion, region) 133. The camera part 133 comprises a camera opening 134, flash opening 135 and sensor opening 136.

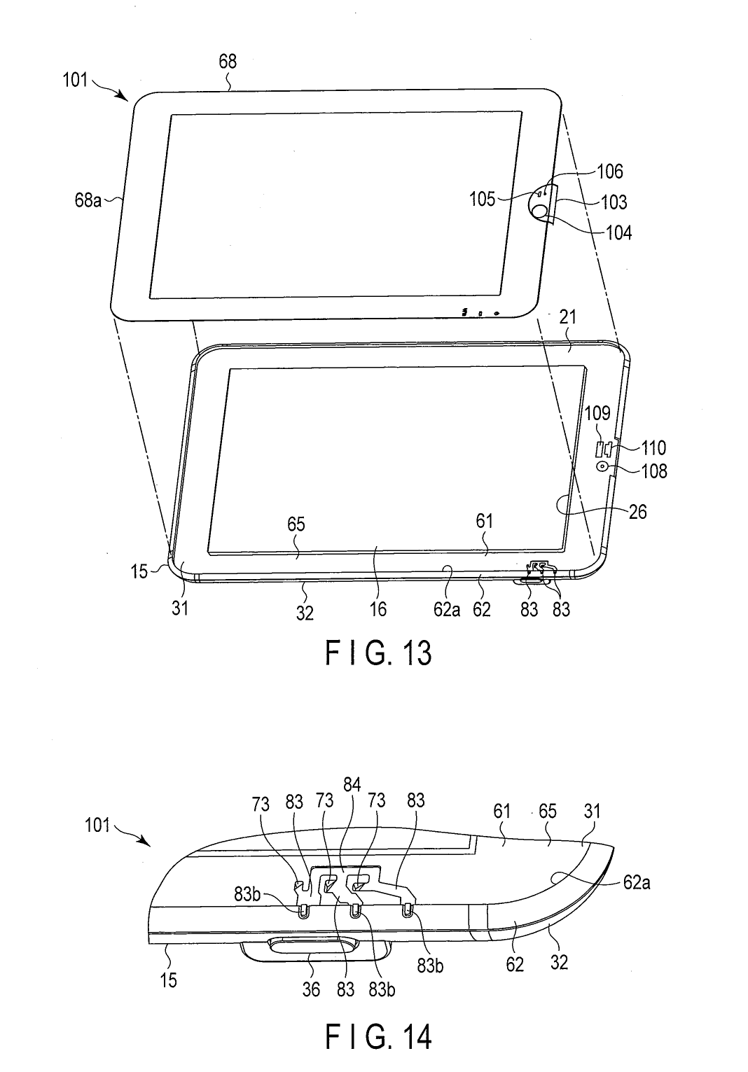

FIG. 13 is an exemplary perspective view of the tablet computer 131 in a disassembled fashion. As shown in FIG. 13, the camera part 133 is provided upon a panel 68. The panel 68 is formed of, for example, a glass panel attached with an electrostatic touchpanel.

The camera opening 134 exposes at least a part of a camera unit 138 stored inside the casing 15. The camera unit 138 comprises an optical sensor such as CMOS sensor and a lens. The flash opening 135 exposes a lens 139, for example. The lens 139 is illuminated by a light emitting device such as an LED stored inside the casing 15. The sensor opening 136 exposes, for example, the other lens 140. The lens 140 guides light outside the casing 15 to an optical sensor such as an illumination sensor stored inside the casing 15.

As shown in FIG. 12, a button member 36 which is, for example, a power button projects from the sidewall 34. As in the first embodiment, the button member 36 is inserted into a button opening 35 on the sidewall 34. The button opening 35 is covered by a keypad 38. The keypad 38 is pressed against the sidewall 34 by a retainer 43 of a fixing member 41.

The panel 68 and notched portions 76 on a edge portion 62 form three second openings 78. Each of the second openings 78 exposes second end 83b of the lens part 83. The panel 68 displays a plurality of diagrams corresponding to the lens parts 83 exposed from the second openings 78.

FIG. 14 is an exemplary perspective view showing a part of the disassembled tablet computer 131 enlarged. As shown in FIG. 14, a part of the lens part 83 facing the panel 68 forms a flat surface substantially the same as an outer surface 65 of the wall portion 61.

In the tablet computer 131 with the structure mentioned above, as in the first embodiment, the first openings 73 are sealed by the transparent member 91 fixed to the wall portion 61 from the inside of the casing 15. Thereby, liquid such as water is prevented from entering inside the casing 15 from the first openings 73. That is, even the tablet computer 131 whose design exposes the lens parts 83 out of the casing 15 can resist intrusion of a liquid. Thus, design of the waterproof structured tablet computer 131 can be carried out with a great degree of freedom.

As mentioned above, the waterproof structure is not limited to the TV 10 or the tablet computer 131, but applicable to other electronic apparatuses such as, for example, a portable computer, a personal digital assistant (PDA), a cellular phone, and a smartphone.

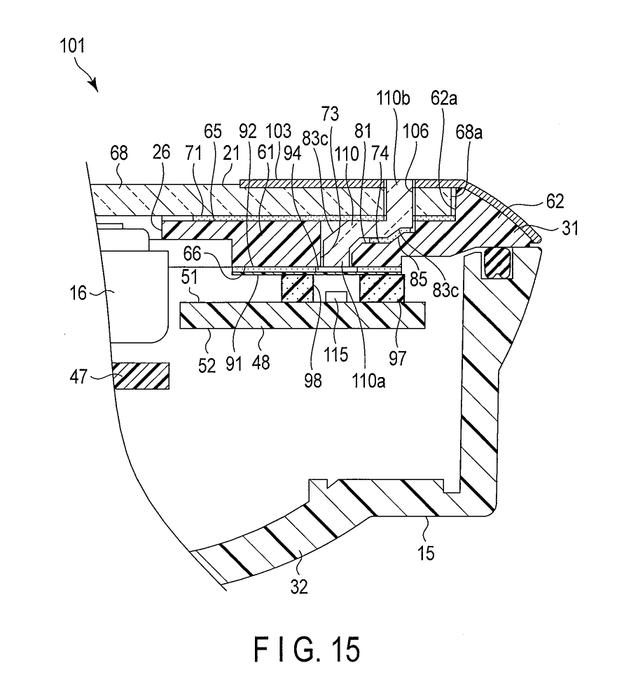

Hereinafter, referring to FIG. 15, the third embodiment is described. FIG. 15 is an exemplary cross-sectional view showing a part of the tablet computer 131 according to the third embodiment. In the third embodiment, a sensor opening 136 is an example of the second opening and a lens 140 is an example of a lens part.

An illumination sensor 145 is mounted on a first surface 51 of a module circuit board 48. The illumination sensor 145 is an example of electronic components and optical sensor. The illumination sensor 145 faces the first opening 73.

The lens 140 is arranged on the intermediate part 81 between the first opening 73 and the sensor opening 136. The lens 140 comprises a first end 140a stored in the first opening 73 and a second end 140b exposed outside the casing 15 from the sensor opening 136.

In the tablet computer 131 with the structure mentioned above, as in the first embodiment, the first opening 73 is sealed by the transparent member 91 fixed to the wall portion 61 from the inside of the casing 15. Thereby, even the tablet computer 131 whose design exposes the lens 140 out of the casing 15 can resist intrusion of liquid, and thus, design of the waterproof structured tablet computer 131 can be carried out with a great degree of freedom.

As mentioned above, the second opening may be the second opening 78 exposing the lens part 83 illuminated by the LED 96, the sensor opening 136 exposing the lens 140 guiding light to the illumination sensor 111, or the like. The second opening may be the other openings such as, for example, the camera opening 134 exposing the camera unit 138 and the flash opening 135 exposing the lens 139 illuminated by the light emitting device.

The term “waterproof” used in the present specification is not limited to total blocking of intrusion of liquid. The term “waterproof” includes, meanings of, for example, preventing intrusion of liquid, packing, shutting up liquid, making a dam, filling up a gap, partially (temporally) stopping water running, etc. Furthermore, the term “waterproof” includes a simple “narrowed part in a passage”.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the embodiments described above, the mask 31 and panel 68 are introduced as an example of the first and second parts. However, the present invention is not limited thereto. Specifically, the base 32 may be an example of the first part and the mask may be an example of the second part.

Furthermore, the first and second double-sided tapes 71 and 85 may seal the entire part of the intermediate part 81. Furthermore, the first opening 73 and the second opening 78 may be overlapped with each other. The electronic component is not limited to light emitting devices such as LED 96 or an optical sensor such as illumination sensor 111, but may also be other component such as a connector and a speaker.

What is claimed is:

1. A waterproof structure comprising:
a casing comprising:
a first part comprising a wall comprising a first opening,
a second part attached to the first part to cover the first opening, and
a second opening connected to the first opening;
a circuit board in the casing comprising an electronic component facing the first opening;
a lens part comprising
a first end portion in the first opening, and
a second end portion exposed through the second opening;
a first waterproof adhering part configured to fix the lens part to the casing, and to seal at least a part of an intermediate part between the first opening and the second opening, the intermediate part including a part of the lens part;
a transparent member configured to seal the first opening from inside of the casing; and
a second waterproof adhering part configured to fix the transparent member to the wall.

2. A waterproof structure comprising:
a casing comprising a wall comprising a first opening;
a circuit board in the casing comprising an electronic component facing the first opening;
a lens part exposed outside the casing, at least a part of the lens part in the first opening; and
a transparent member fixed to the wall inside of the casing, the transparent member configured to seal the first opening.

3. The waterproof structure of claim 2, further comprising a first waterproof adhering part configured to fix the lens part to the casing.

4. The waterproof structure of claim 3, wherein the first waterproof adhering part is configured to seal at least a part of a region between the first opening and the casing.

5. The waterproof structure of claim 2, further comprising a second waterproof adhering part configured to fix the transparent member to the wall.

6. The waterproof structure of claim 4, further comprising a second waterproof adhering part configured to fix the transparent member to the wall.

7. The waterproof structure of claim 2, wherein
the casing comprises a second opening connected to the first opening and exposed outside the casing while at least a part of the second opening not overlapping with the first opening, and
the lens part is exposed through the second opening.

8. The waterproof structure of claim 6, wherein
the casing comprises a second opening connected to the first opening and exposed outside the casing while at least a part of the second opening not overlapping with the first opening, and
the lens part is exposed through the second opening.

9. The waterproof structure of claim 2, wherein
the casing comprises a first part comprising the wall and a second part attached to the first part to cover the first opening, and
the second opening is formed with the first and second parts.

10. The waterproof structure of claim 8, wherein
the casing comprises a first part comprising the wall and a second part attached to the first part to cover the first opening, and
the second opening is formed with the first and second parts.

11. The waterproof structure of claim 10, wherein
the casing comprises an intermediate part connecting the first opening and the second opening,
a part of the lens part is in the intermediate part, and
the first waterproof adhering part is further configured to seal at least a part of the intermediate part.

12. The waterproof of claim 11, wherein
the intermediate part is formed with the first and second parts of the casing, and
a part of the first waterproof adhering part is further configured to fix the first part to the second part.

13. The waterproof structure of claim 2, further comprising a pressing member attached to the circuit board, the pressing member comprising a container configured to contain the electronic component, open toward the first opening, and pressing the transparent member to the wall.

14. The waterproof structure of claim 12, further comprising a pressing member attached to the circuit board, the pressing member comprising a container configured to contain the electronic component, open toward the first opening, and pressing the transparent member to the wall.

15. The waterproof structure of claim 2, wherein the electronic component is configured to emit light.

16. The waterproof structure of claim 14, wherein the electronic component is configured to emit light.

17. The waterproof structure of claim 2, wherein the electronic component comprises an optical sensor.

18. The waterproof structure of claim 14, wherein the electronic component comprises an optical sensor.
